(19) United States
(12) Patent Application Publication
(10) Pub. No.: US 2020/0044007 A1
(43) Pub. Date: Feb. 6, 2020

(54) DISPLAY DEVICE

(71) Applicant: INT TECH CO., LTD., HSINCHU COUNTY (TW)

(72) Inventor: YU-JOU CHEN, HSINCHU COUNTY (TW)

(21) Appl. No.: 16/394,333

(22) Filed: Apr. 25, 2019

(30) Foreign Application Priority Data
Aug. 1, 2018 (TW) 107126708

(51) Int. Cl. H01L 27/32

(52) U.S. Cl. CPC H01L 27/3276; H01L 27/3265; H01L 27/124; H01L 27/3248; H01L 27/3262

(57) ABSTRACT

The present disclosure provides display device. The display device includes a substrate having an upper surface and a circuit layer stacked on the upper surface of the substrate. The circuit layer includes a dielectric layer and a wire. The wire extends in a Y direction, wherein the Y direction is different from an X direction. The X direction is perpendicular to the upper surface of the substrate. The wire includes a plurality of conductive interconnects disposed in the dielectric layer, the adjacent conductive interconnects are electrically connected, and adjacent conductive interconnects are disposed at different distances from the upper surface of the substrate.

### PRIORITY CLAIM AND CROSS REFERENCE

This application claims priority of Taiwan Patent application Ser. No 107126708 filed on Aug. 1, 2018, which is incorporated by reference in its entirety.

### BACKGROUND

Due to their great potential for application to display devices, organic light-emitting diodes (OLEDs) and flexible display devices have recently become very important to the consumer-technology community and the display industry, and now attract much attention in research and development.

However, display technology is currently experiencing obstacles in the development process. First, as panel sizes increase, lengths of a wire connected to pixels in a circuit portion, e.g., a scan line or a signal line, may be increased accordingly. Therefore, an increase in the length of the display panel leads to an increase in the length of a wire, such as a wire connected to a scan line, a data line or a V_{DD} line in the circuit portion of the layout. Therefore, a so-called antenna effect, in which charge is accumulated in a wire during a manufacturing step that uses plasma, such as dry etching, is likely to occur, and the antenna effect increases the probability of electrostatic destruction of the wire by discharge of the charge accumulated in the wire. Thus, the probability of electrostatic destruction of the wire is increased by an increase in the length of the wire, thereby reducing the manufacturing yield of the display device.

In addition, the increase in the length of the wire can also lead to the loading effect when conductive material is etched during a manufacturing step, especially when the wire is very dense. The loading effect causes the etching efficiency of a smaller window to be less than that of a larger window. The etching is difficult to pass through the small window, and the composite produced by etching is difficult to diffuse. As such, the loading effect may cause short circuit of the display device, resulting in decreased yield of the display device.

Second, if the display device includes a flexible substrate, the display device is flexible Bending a flexible display device can cause stress inside the display device, and any damage caused to the wire by stress such as breakage will be detrimental to the reliability of the display device.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic diagram of a display device in accordance with some embodiments of the present disclosure.

FIG. 2 is a cross-sectional view of a display device in accordance with some embodiments of the present disclosure.

FIG. 3 is a perspective view of a conductive interconnect in accordance with some embodiments of the present disclosure.

FIG. 4 is a perspective view of a conductive interconnect in accordance with some embodiments of the present disclosure.

FIG. 5 is a perspective view of a conductive interconnect in accordance with some embodiments of the present disclosure.

FIG. 6 is a perspective view of a conductive interconnect in accordance with some embodiments of the present disclosure.

FIG. 7 is a top view of a wire in accordance with some embodiments of the present disclosure.

FIG. 8 is a cross-sectional view of a display device in accordance with some embodiments of the present disclosure.

FIG. 9 is a top view of a wire in accordance with some embodiments of the present disclosure.

FIG. 10 is a cross-sectional view of a display device in accordance with some embodiments of the present disclosure.

FIG. 11 is a top view of a wire in accordance with some embodiments of the present disclosure.

FIG. 12 is a cross-sectional view of a display device in accordance with some embodiments of the present disclosure.

FIG. 13 is a cross-sectional view of a display device in accordance with some embodiments of the present disclosure.

FIG. 14 is a perspective view of a conductive interconnect in accordance with some embodiments of the present disclosure.

FIG. 15 is a perspective view of a conductive interconnect in accordance with some embodiments of the present disclosure.

FIG. 16 is a top view of a wire in accordance with some embodiments of the present disclosure.

FIG. 17 is a top view of a wire in accordance with some embodiments of the present disclosure.

FIG. 18 is a top view of a wire in accordance with some embodiments of the present disclosure.

FIG. 19 is a cross-sectional view of a display device in accordance with some embodiments of the present disclosure.

FIG. 20 is an electrical circuit diagram of a pixel-driving circuit.

FIG. 21 is a top view showing an embodiment of a display device in accordance with some embodiments of the present disclosure.

FIG. 22 is a cross-sectional view of a display device in accordance with some embodiments of the present disclosure.

FIG. 23 is a cross-sectional view of a display device in accordance with some embodiments of the present disclosure.

FIG. 24 is a cross-sectional view of a display device in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting.

Before addressing illustrated embodiments specifically, advantageous features and certain aspects of the exemplary embodiments are discussed generally. General aspects of embodiments described herein include a wire including a plurality of conductive interconnects, wherein the conductive interconnects are electrically connected.

Further, it should be understood that when an element is referred to as being “connected to” or “coupled to” another element, it may be directly connected to or coupled to the other element, or intervening elements may be present.

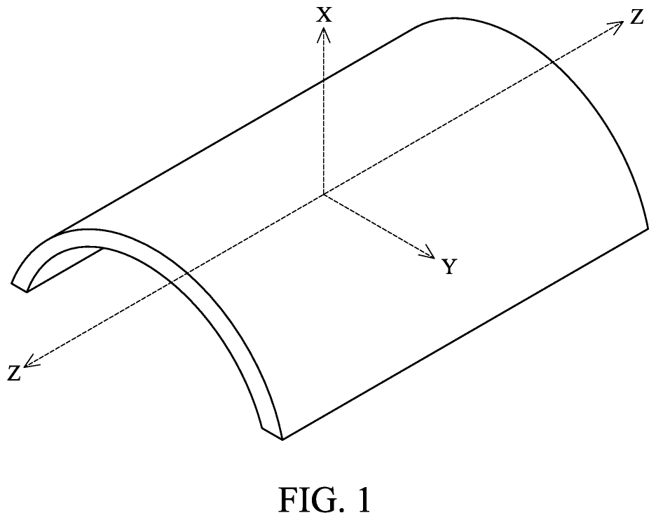

FIG. 1 is a schematic diagram of a display device in accordance with some embodiments of the present disclosure, illustrating a state in which the display, device is bent in a direction. As shown in FIG. 1, in some embodiments, the display device is bent in a Z direction, and in this embodiment, the display device is curved so as to be convex, but the disclosure is not limited thereto. In some embodiments, the display device is curved in such a manner that the display device is concave. The Z direction is different from the X direction and the Y direction, and the Y direction and the Z direction may be perpendicular to each other, or may otherwise form an included angle greater than zero. In some embodiments, the Z direction is substantially perpendicular to the X direction and the Y direction. In some embodiments, the display device is bent in the Y direction or the Z direction.

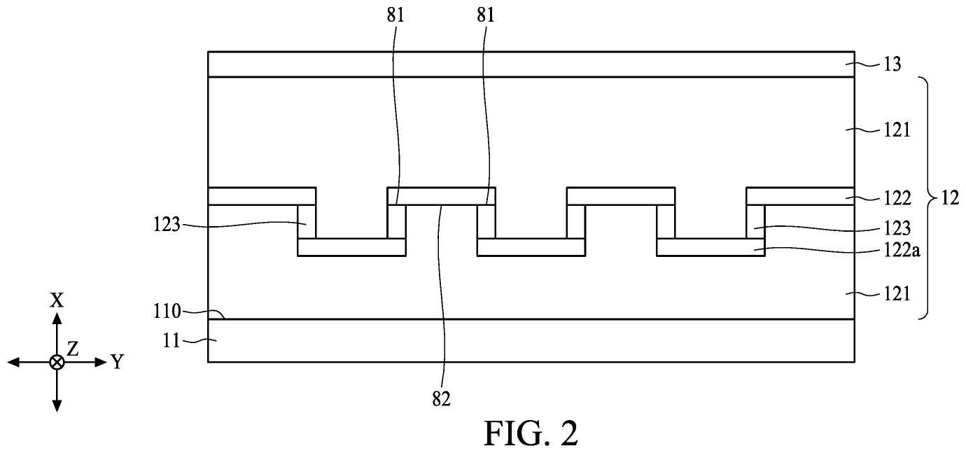

FIG. 2 is a schematic cross-sectional view illustrating a display device according to aspects of the present disclosure in some embodiments. As shown in FIG. 2, the display device includes a substrate 11, a circuit layer 12, and a pixel layer 13. In some embodiments, the circuit layer 12 includes a circuit portion. The circuit portion is configured to include a circuit. The substrate 11 has an upper surface 110, and the circuit layer 12 is stacked on the upper surface 110 of the substrate 11. The circuit layer 12 includes a dielectric layer 121 and a wire 122. The pixel layer 13 is disposed on the circuit layer 12.

In some embodiments, the wire extends in a Y direction, wherein the Y direction is different from an X direction. The X direction is perpendicular to the upper surface of the substrate. In some embodiments, the Y direction is substantially perpendicular to the X direction. The wire 122 includes a plurality of conductive interconnects 122a disposed in the dielectric layer 121, and adjacent pairs of the conductive interconnects 122a are electrically connected. Two conductive interconnects 122a of an adjacent pair are at different distances above the upper surface 110 of the substrate 11. In other words, the adjacent conductive interconnects 122a are arranged in a manner offset from each other. Compared to an integrally formed wire, the wire 122, which is electrically connected by a plurality of conductive interconnects 122a, is subjected to significantly reduced tensile stress when the display device is bent, thereby making the wire 122 less susceptible to breakage and more durable, and thereby increasing the reliability of the display device. Further, the configuration of the wire 122 may prevent accumulation of charge in a single conductive interconnect 122a by the antenna effect, and may also reduce the chance of loading effects during production. In some embodiments, the conductive interconnects 122a can be coupled to a semiconductor component according to the actual needs. The semiconductor component can include, but is not limited to, polysilicon.

Each of the conductive interconnects 122a can be designed to have the same or different sizes, shapes, and widths as desired, and can include the same or different conductive materials. In some embodiments, the conductive material can be, but not is limited to, a metal or a metal alloy. In some embodiments, each of the conductive interconnects 122a is in a strip shape. In some embodiments, the conductive interconnects 122a are arranged substantially in the same direction. In some embodiments, each of the conductive interconnects 122a may be arranged in any direction perpendicular to the X direction. In some embodiments, the plurality of conductive interconnects 122a may include both conductive interconnects 122a arranged in the Y direction and conductive interconnects 122a arranged in the Z direction. In some embodiments, the plurality of conductive interconnects 122a are arranged in the Y direction. In some embodiments, the plurality of conductive interconnects 122a are arranged in the Z direction.

By controlling the length of the conductive interconnects 122a, the wires 122 can be made suitable for repeated bending. In some embodiments, each of the conductive interconnects 122a has a length of 100 um to 500 um.

In some embodiments, the circuit layer 12 further includes a conductive via 123 configured to electrically connect the adjacent conductive interconnects 122a. In some embodiments, the circuit layer 12 includes a plurality of conductive vias 123, wherein each of the conductive vias 123 is electrically connected to the adjacent conductive interconnects 122a, and the conductive interconnects 122a are electrically connected to form the wires 122.

In some embodiments, the shape and size of each of the conductive vias 123 are not limited, and may be adjusted according to the actual needs. The conductive vias 123 can be designed to have the same or different sizes and shapes as desired, and each conductive via 123 may include the same or different conductive materials. In some embodiments, the conductive material can be, for example but not limited to, a metal or a metal alloy.

In some embodiments, the conductive interconnect 122a includes one or more contact regions 81, and one or more non-contact regions 82. The contact region 81 is configured to be in contact with the adjacent conductive interconnect 122a or the conductive via 123. The region outside the contact region 81 is the non-contact region 82. In some embodiments, the non-contact region 82 is substantially covered by a dielectric layer 121.

In some embodiments, each of the conductive interconnects 122a has two contact regions 81, and the contact regions 81 are separated from each other. In some embodiments, each of the conductive interconnects 122a has two contact regions 81 disposed at opposite sides, and a non-contact region 82 disposed between the two contact regions 81. In some embodiments, the two contact regions 81 of each conductive interconnect 122a may have the same or different areas and shapes, and may be disposed on the same or different faces of the conductive interconnect 122a.

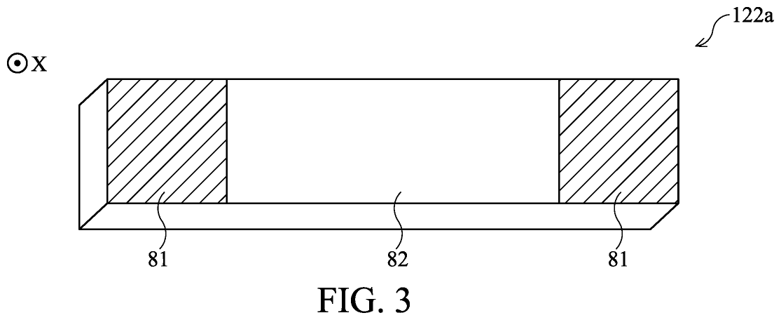

FIG. 3 is a perspective view of a conductive interconnect 122a in accordance with some embodiments of the present disclosure. In some embodiments, as shown in FIG. 3, the contact regions 81 are located at both ends of the same face of the conductive interconnect 122a, and the region outside the contact region 81 is the non-contact region 82.

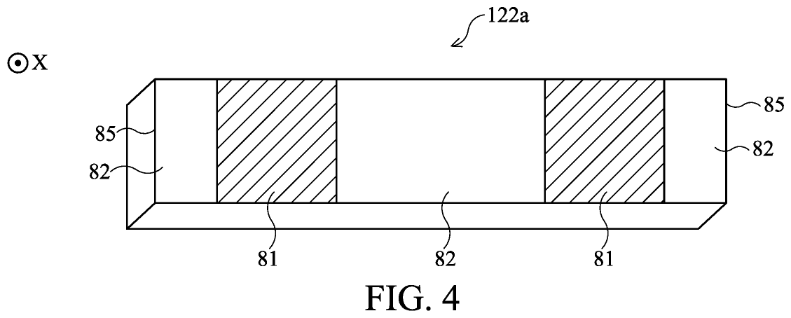

FIGS. 4 to 6 are perspective views of a conductive interconnect 122a in accordance with some embodiments of the present disclosure. In some embodiments, the contact regions 81 and the non-contact region 82 on the same face of the conductive interconnect 122a may be arranged, for example, as shown in FIGS. 4 to 6, but are not limited thereto.

In some embodiments, the contact regions 81 may be disposed in a region other than at the two ends of the conductive interconnect 122a. As shown in FIG. 4, the non-contact regions 82 are disposed at the two ends of the conductive interconnect 122a, and the contact regions 81 are disposed apart from each other and between the two ends. In some embodiments, a distance between a periphery 85 of the conductive interconnect 122a and the contact region 81 is greater than 0.

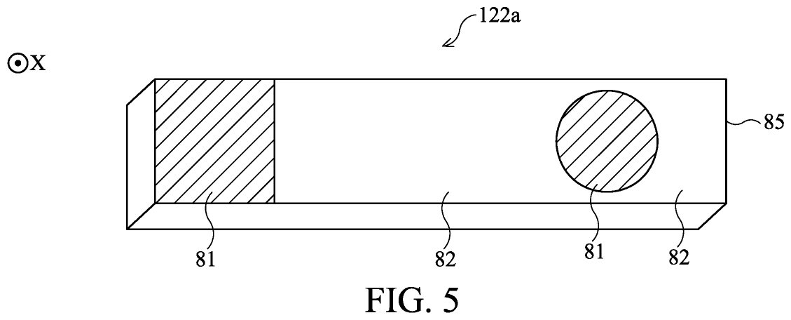

In some embodiments, as shown in FIG. 5, one of the contact regions 81 is disposed at one end of the conductive interconnect 122a, and the non-contact region 82 is disposed at the other end. Another contact region 81 is disposed between the two ends of the conductive interconnect 122a. The distance between the periphery 85 of the conductive interconnect 122a and the contact region 81 is greater than 0.

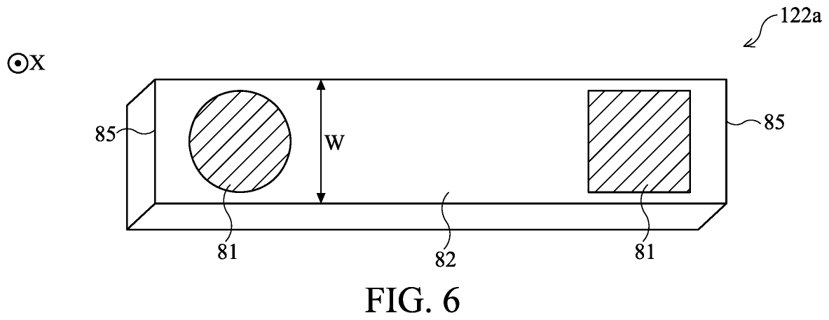

In some embodiments, as shown in FIG. 6, the contact regions 81 have different areas and shapes, and each contact region 81 is narrower than the width W of the conductive interconnect 122a.

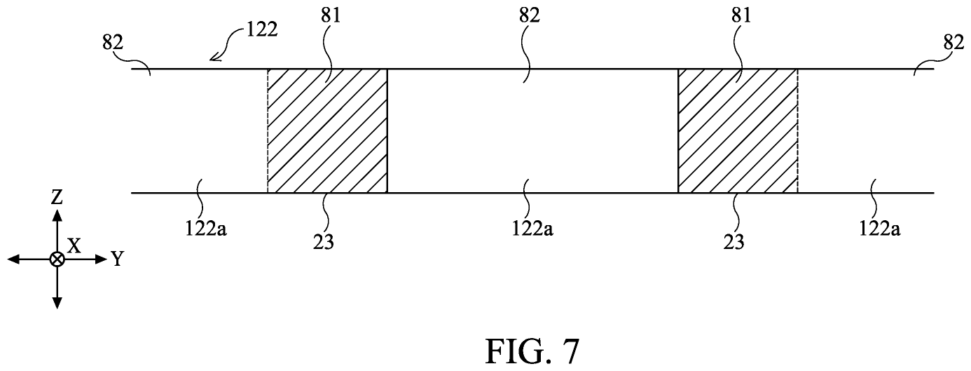

FIG. 7 is a top view of a portion of a wire in accordance with some embodiments of the present disclosure. In some embodiments, the conductive interconnects 122a as shown in FIG. 2 are electrically connected through the conductive vias 123. As shown in FIGS. 2, 3 and 7, the conductive vias 123 are disposed between the contact region 81 of the adjacent conductive interconnects 122a. In some embodiments, the contact regions 81 of each of the conductive interconnects 122a are disposed at opposite ends of the same face of the conductive interconnect 122a, similar to the arrangement shown in FIG. 3. In some embodiments, the adjacent conductive interconnects 122a have the same width.

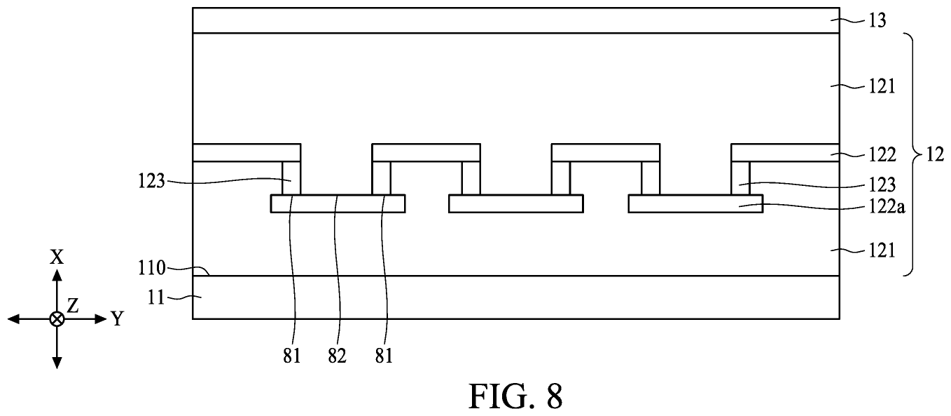

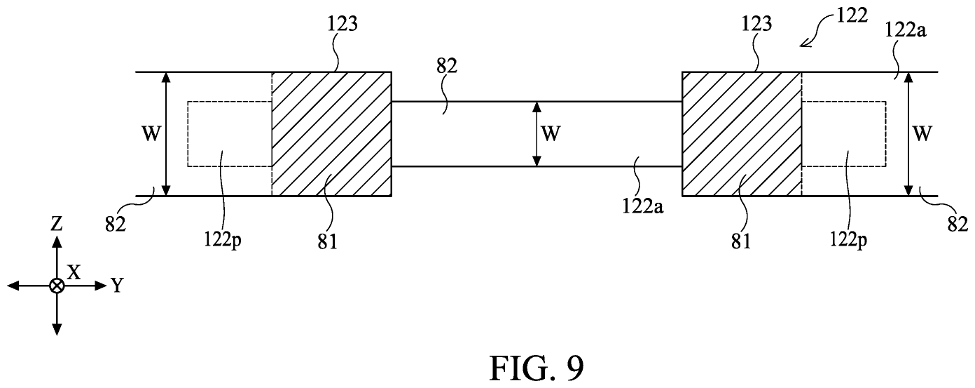

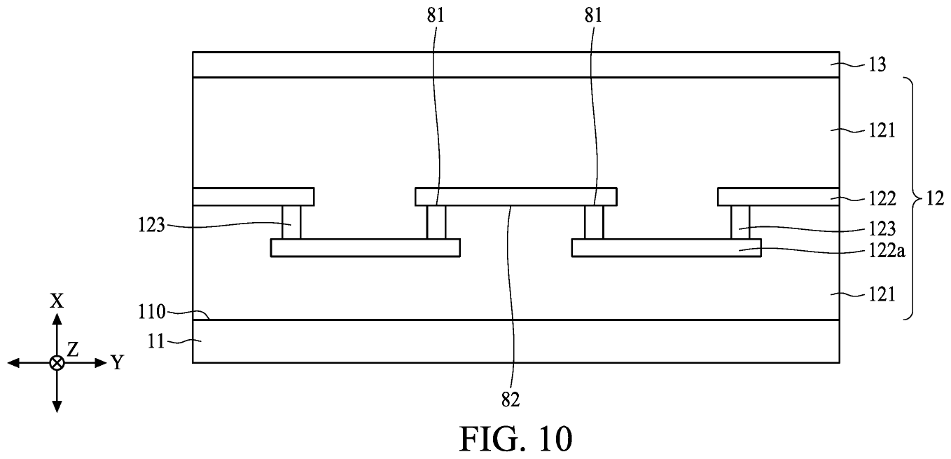

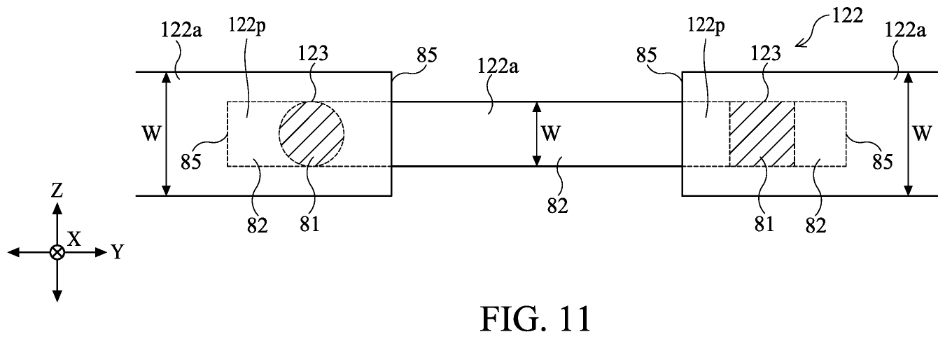

In some embodiments, the conductive interconnects 122a and the conductive vias 123 may be arranged, for example, as shown in FIGS. 8 to 11, but are not limited thereto. FIG. 8 is a cross-sectional view of a display device in accordance with some embodiments of the present disclosure. FIG. 9 is a top view illustrating a portion of the wire 122 shown in FIG. 8. FIG. 10 is a cross-sectional view of a display device in accordance with some embodiments of the present disclosure. FIG. 11 is a top view illustrating a portion of the wire 122 shown in FIG. 10. In some embodiments, adjacent conductive interconnects 122a have different widths W.

In some embodiments, as shown in FIGS. 8 and 9, the conductive interconnects 122a shown in FIGS. 3 and 4 are electrically connected through the conductive vias 123. In an embodiment, the maximum width of the conductive via 123 measured in the Z direction is equal to the width W of the conductive interconnect 122a. In an embodiment, the maximum width of the conductive via 123 measured in the Z direction is greater than the width W of the conductive interconnect 122a. In some embodiments, the width W of the lower conductive interconnect 122a is less than the width W of the upper conductive interconnect 122a. In some embodiments, the lower conductive interconnect 122a protrudes beyond the conductive vias 123 in the Y direction (wherein the dashed lines in FIG. 9 represents the protruding portions 122p of the lower conductive interconnect 122a), and the lower conductive interconnect 122a is overlapped by the contact regions 81 and the non-contact region 82 of the upper conductive interconnect 122a from a top view.

In some embodiments, as shown in FIGS. 10 and 11, the contact regions 81 are disposed apart from each other and disposed between the two ends, and the distance between the periphery 85 of the conductive interconnect 122a and the contact region 81 is greater than 0. In some embodiments, the conductive interconnects 122a shown in FIGS. 4 and 6 are electrically connected through the conductive vias 123. In some embodiments, the width of the conductive via 123 is less than the width W of some of the conductive interconnects 122a. In some embodiments, the contact regions 81 of the lower conductive interconnect 122a have different areas and shapes, and the width W of the lower conductive interconnect 122a is less than the width W of the upper conductive interconnect 122a, In some embodiments, the lower conductive interconnect 122a protrudes beyond the conductive vias 123 in the Y direction (wherein the dashed line in FIG. 11 represents the protruding portion 122p of the lower conductive interconnect 121a), and the lower conductive interconnect 122a is overlapped by the contact regions 81 and the non-contact region 82 of the upper conductive interconnect 122a from a top view.

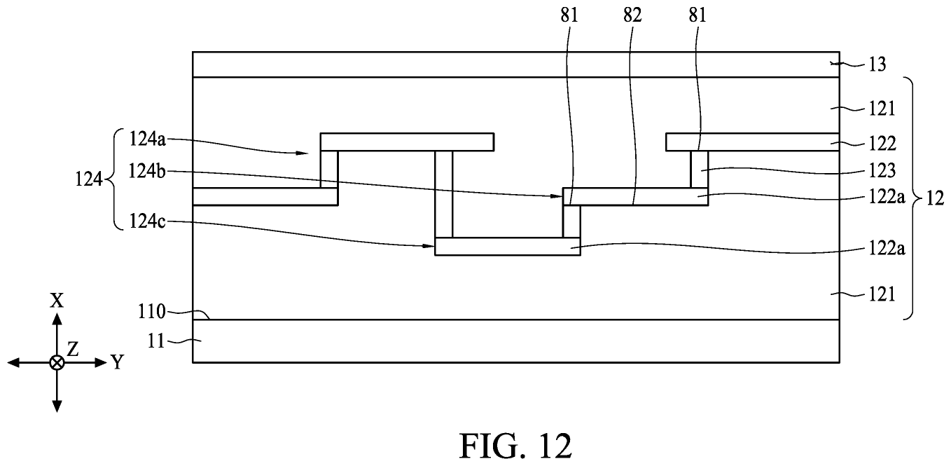

In some embodiments, as shown in FIG. 12, the wire 122 includes a plurality of conductive layers 124, which are arranged in an offset manner. In some embodiments, each of the conductive layers 124a, 124b, 124c includes at least one conductive interconnect 122a. The conductive interconnects 122a of different conductive layers 124a, 124b, 124c may include the same or different conductive materials.

FIG. 12 is a cross-sectional view of a display device in accordance with some embodiments of the present disclosure. The number of the conductive layers 124 included in the wire 122 is not particularly limited and can be adjusted according to actual needs.

In some embodiments, as shown in FIG. 12, the wire 122 includes a first conductive layer 124a, a second conductive layer 124b, and a third conductive layer 124c. In some embodiments, each of the first conductive layer 124a, the second conductive layer 124b, and the third conductive layer 124c includes at least one conductive interconnect 122a. In some embodiments, the third conductive layer 124c, the second conductive layer 124b, and the first conductive layer 124a are sequentially disposed over the upper surface 110 of the substrate 11. The first conductive layer 124a, the second conductive layer 124b, and the third conductive layer 124c are arranged in an offset manner.

In some embodiments, the first conductive layer 124a includes a portion of the conductive interconnects 122a, the second conductive layer 124b includes another portion of the conductive interconnects 122a, and the third conductive layer 124c includes the remainder of the conductive interconnects 122a.

In some embodiments, the adjacent conductive interconnects partially overlap each other from a top view, such that the conductive interconnects 122a are electrically connected to form the wires 122. The manner of the overlapping of the conductive interconnects 122a is not particularly limited, as long as the wires 122 are formed by electrically connecting the conductive interconnects 122a.

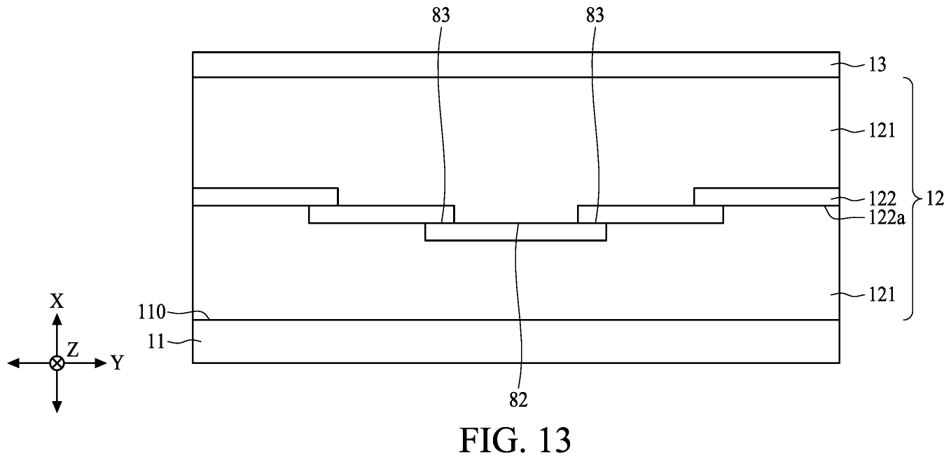

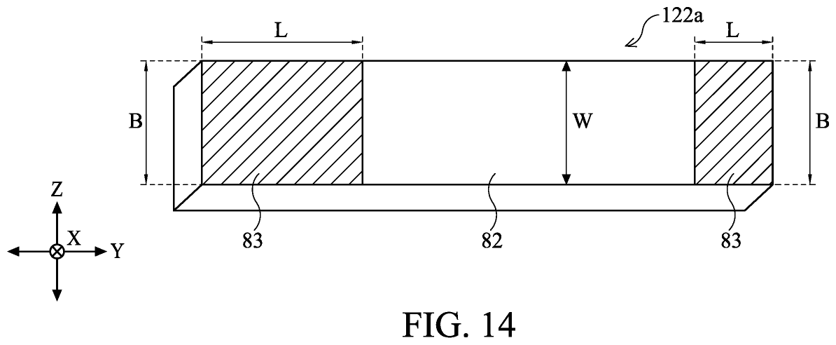

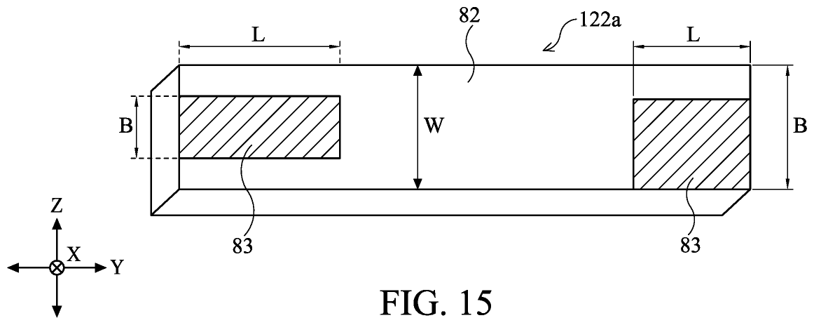

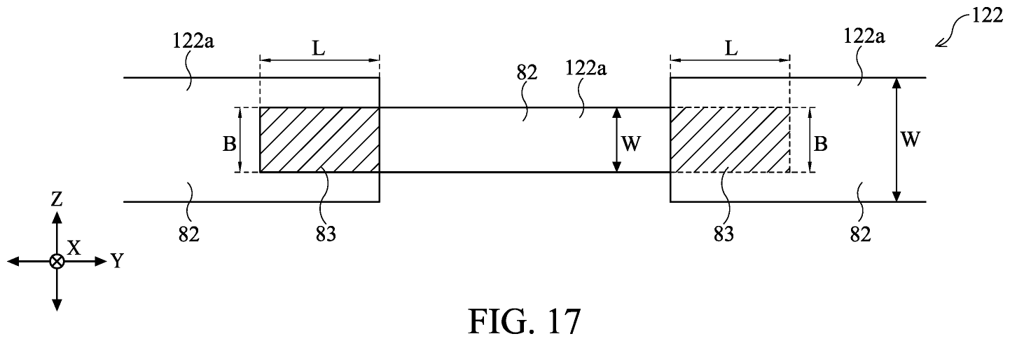

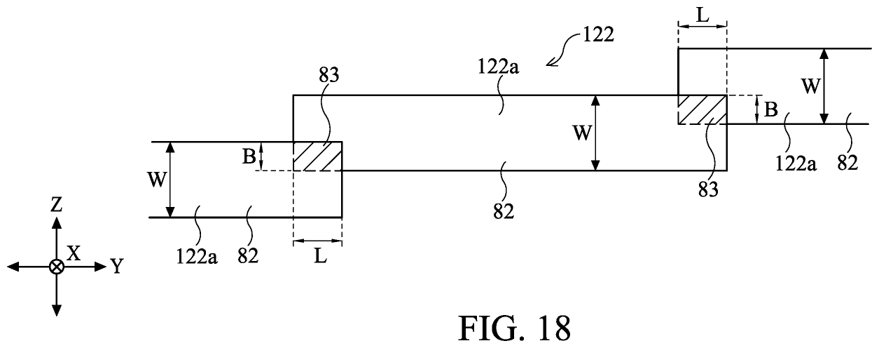

FIG. 13 is a cross-sectional view of a display device in accordance with some embodiments of the present disclosure. FIGS. 14 and 15 are perspective views of the conductive interconnects 122a of the display device shown in FIG. 13. FIGS. 17 and 18 are top views illustrating a portion of the wire 122 shown in FIG. 13.

In some embodiments, as shown in FIG. 13, the adjacent conductive interconnects 122a are partially overlapping and are stepped. In some embodiments, the conductive interconnects 122a are positioned at three different distances above the upper surface 110 of the substrate 11.

In some embodiments, each of the conductive interconnects 122a is electrically coupled to two adjacent conductive interconnects 122a. In some embodiments, the conductive interconnect 122a includes at least one overlap region 83, and one or more non-contact regions 82. The overlap region 83 is configured to overlap the adjacent conductive interconnects 122a from a top view and configured to be electrically coupled to the adjacent conductive interconnects 122a, and the region outside the overlap region 83 is the non-contact region 82. In some embodiments, the non-contact region 82 is substantially covered by a dielectric layer 121.

In an embodiment, each of the conductive interconnects 122a has two overlap regions 83, and the overlap regions 83 are separated from each other. In some embodiments, each of the conductive interconnects 122a has two overlap regions 83 disposed at opposite sides, and a non-contact region 82 disposed between the two overlap regions 83. In some embodiments, the two overlap regions 83 of each conductive interconnect 122a may have the same or different areas and shapes, and may be disposed on the same or different faces of the corresponding conductive interconnect 122a.

In some embodiments, as shown in FIGS. 14 and 15, the overlap regions 83 and the non-contact region 82 are on the same face of the conductive interconnect 122a. In other embodiments, the overlap regions 83 may be located, for example, at both ends of the same face of the conductive interconnect 122a, and the non-contact region 82 comprises the remaining region of the conductive interconnect 122a. In some embodiments, the two overlap regions 83 of each conductive interconnect 122a have different areas and shapes. In some embodiments, each of the conductive interconnects 122a is disposed in a strip shape, and each of the overlap regions 83 has a length L in the Y direction and a width B in the Z direction. In some embodiments, the length L is greater than 0 and less than or equal to the length of either of the adjacent conductive interconnects 122a measured along the Y direction. In some embodiments, the width B is greater than 0 and less than or equal to the width W of either of the adjacent conductive interconnects 122a measured in the Z direction.

In some embodiments, as shown in FIG. 14, the length L is greater than 0 and less than the length of the conductive interconnect 122a measured along the Y direction. In some embodiments, the width B is equal to the width W of the conductive interconnects 122a measured in the Z direction.

In some embodiments, as shown in FIG. 15, the length L is greater than 0 and less than the length of the conductive interconnect 122a measured along the Y direction. In some embodiments, the width B is greater than 0 and less than the width W of the conductive interconnects 122a measured in the Z direction.

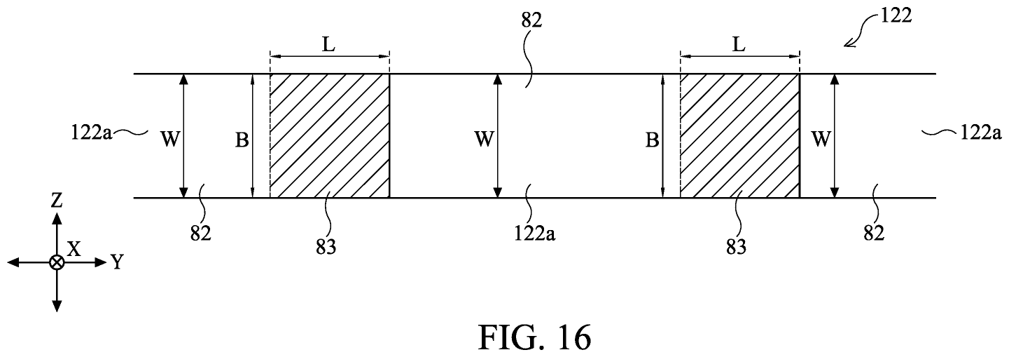

In some embodiments, as shown in FIG. 16, adjacent conductive interconnects 122a have the same width W, and the width B of the overlap regions 83 measured in the Z direction is equal to the width W of the conductive interconnects 122a. For the conductive interconnect 122a disposed between the upper and lower conductive interconnects 122a, the overlap regions 83 are respectively disposed on opposite faces of the conductive interconnect 122a.

In some embodiments, the adjacent conductive interconnects 122a may have different widths W and/or may be arranged in an offset manner from a top view. In some embodiments, as shown in FIG. 17, the adjacent conductive interconnects 122a have different widths W, the width B of some conductive interconnects 122a is less than the width W of the corresponding conductive interconnect 122a, and the width B of some conductive interconnects 122a is equal to the width W of the corresponding conductive interconnect 122a. In some embodiments, for the conductive interconnect 122a disposed between the upper and lower conductive interconnects 122a, the width B of the overlap region 83 is equal to the width W of the conductive interconnects 122a, and the width B is less than the width W of each of the upper and lower conductive interconnects 122a.

In some embodiments, as shown in FIG. 18, adjacent conductive interconnects 122a have equal widths W, and are arranged so as to be offset in both Y and Z directions. In some embodiments, the two overlap regions 83 of some conductive interconnects 122a are disposed on different faces. In some embodiments, for the conductive interconnect 122a disposed between the upper and lower conductive interconnects 122a, the overlap regions 83 are respectively disposed at opposite corners of the upper face and the lower face of the conductive interconnect 122a, and the width B of the overlap regions 83 measured in the Z direction is less than the width W of the conductive interconnect 122a.

In some embodiments, the substrate 11 is flexible and can be normally operated while being bent by an external force. In some embodiments, the substrate 11 has different bending capabilities depending on composition and structure, and can be made of different materials according to different needs. In some embodiments, the substrate 11 may include, for example but not limited to, polyethylene terephthalate (PET), silicone, polyimine (PI), polypropylene (PP), polyethylene naphthalate (PEN), polycarbonates (PC), polyesters (PES), cyclic olefin copolymers (COC), and compositions thereof. In some embodiments, the substrate 11 includes PI.

In some embodiments, the circuit of the circuit portion may be, but is not limited to, a pixel-driving circuit or a transistor circuit. In some embodiments, the transistor circuit may be, but is not limited to, an amorphous germanium thin film transistor (a-Si TFT), a polycrystalline silicon transistor (poly-Si TFT), or an oxide thin film transistor (oxide TFT).

In some embodiments, the dielectric layers 121 include low-k dielectric material. The dielectric constant (k value) of the low-k dielectric material may be lower than 3.0, or lower than about 2.5, and the dielectric material is therefore also referred to as an extreme low-k (ELK) dielectric material. The material of the dielectric layer 121 may include organic dielectric material such as organic silicate glass (OSG), porous methyl silsesquioxane (p-MSQ), hydrogen silsesquioxane (HSQ), a combination thereof, or any other suitable organic low-k or extreme low-k dielectric material. In some embodiments, the material of the dielectric layer 121 may include inorganic dielectric material such as carbon-doped silicon oxide, fluorine-doped silicate glass (FSG), a combination thereof, or any other suitable inorganic low-k or extreme low-k dielectric material. In some embodiments, other suitable dielectric materials, such as silicon oxide or phosphosilicate glass (PSG), may also be used. In some embodiments, the dielectric layer 121 includes silicon oxide.

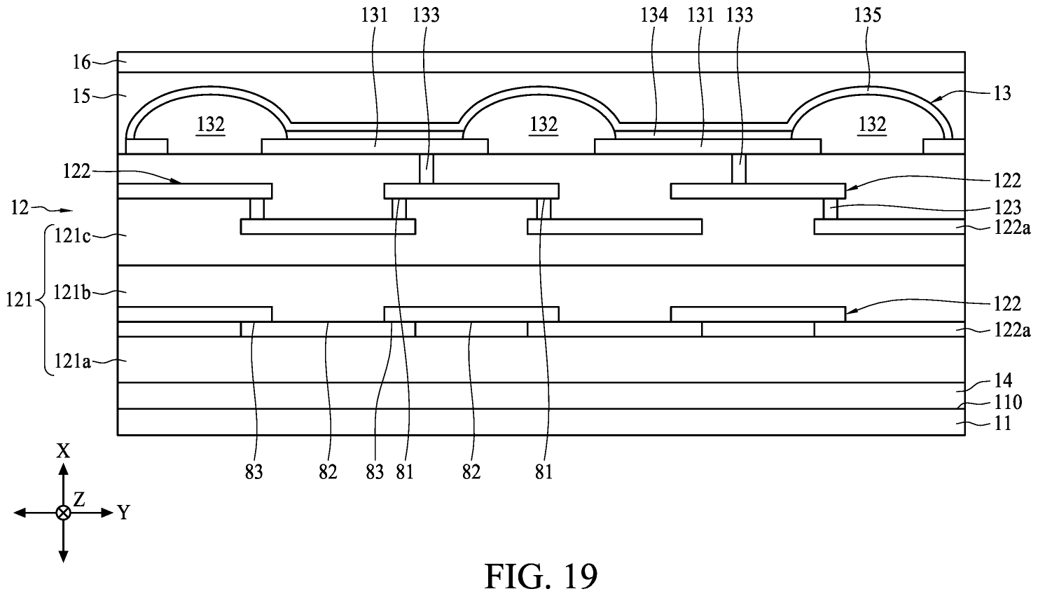

FIG. 19 is a cross-sectional view of a display device in accordance with some embodiments of the present disclosure. In some embodiments, as shown in FIG. 19, the pixel layer 13 includes a plurality of first pixel electrodes 131 disposed on the circuit layer 12, and at least one hump 132 substantially covered the gap between adjacent first pixel electrodes 131. Each first pixel electrode 131 is configured to be connected to one of the wire 122 embedded in the circuit layer 12 at one side through a conductive via 133 and to be in contact with a light emitting layer 134 at the other side. In some embodiments, each first pixel electrode 131 is partially covered by the bump 132. In some embodiments, the pattern of the first electrodes 131 is designed for the pixel arrangement. In some embodiments, the patterned bumps 132 are also called pixel defined layer (PDL). The bump 132 can be formed in different types of shape. In some embodiments, the light emitting layer 134 is configured to be broken into segments, each segment is vertically aligned to a first pixel electrode 131, and each segment may include same or different light emitting materials. In some embodiments, the pixel layer 13 further includes a second pixel electrode 135. In some embodiments, the second pixel electrode 135 is continuously overlies several bumps 132 and the light emitting layer 134. In some embodiments, the first electrode 131 is anode and the second electrode 135 is cathode.

In some embodiments, the display device further includes a buffer layer 14, In some embodiments, the buffer layer 14 is disposed between the upper surface 110 of the substrate 11 and the circuit layer 12 for preventing impurity elements from penetrating through the substrate 11 and for planarizing the surface 110 of the substrate 11. In some embodiments, the display device further includes an encapsulation layer 15 disposed on the pixel layer 13. In an embodiment, the display device further includes a protective layer 16 disposed on the encapsulation layer 15. In an embodiment, the dielectric layer 121 has a plurality of sub-dielectric layers 121a, 121b, 121c stacked in the X direction.

In an embodiment, the circuit layer 12 includes a plurality of wires 122. The manner of electrical connections, sizes, and orientation of the wires 122 may be the same or different, and may be adjusted according to the actual needs. In some embodiments, the wires 122 may be disposed in or between the sub-dielectric layers 121a, 121b, 121c. In some embodiments, the wires 122 may be disposed in one or a plurality of sub-dielectric layers 121a, 121b, 121c. In some embodiments, one or more of the wires 122 may pass through each of the sub-dielectric layers 121a, 121b, 121c. In some embodiments, some of the sub-dielectric layers 121a, 121b, 121c may not be in contact with any of the wires 122.

In some embodiments, the pixel electrode 131 may include indium tin oxide (ITO), indium zinc oxide (IZO), zinc oxide (ZnO), indium oxide (In2O3), indium gallium oxide (IGO), or aluminum zinc oxide (AZO), but is not limited thereto. In some embodiments, the pixel-defining layer 132 can be any physical structure used to define pixels. In some embodiments, the pixel-defining layer 132 may include patterned organic insulating materials such as, but not limited to, polyimine (PI), polyamine, polyacrylic acid, benzocyclobutene, phenol resin, or combinations thereof.

In some embodiments, the buffer layer 4 can be formed from a variety of materials, including inorganic materials, organic materials, or combinations thereof. The inorganic material may be, for example but not limited to, silicon oxide, silicon nitride, silicon oxynitride, aluminum oxide, aluminum nitride, titanium oxide or titanium nitride. The organic material can be, for example but not limited to, polyimine, polyester or polypropylene. In some embodiments, the buffer layer 14 is flexible.

In some embodiments, the encapsulation layer 15 completely covers the pixel layer 13 to prevent external moisture or oxygen from penetrating into the display device. In some embodiments, the encapsulation layer 15 may include an inorganic material such as, but not limited to, tin fluorophosphate glass, bismuth glass, tellurite glass, borate glass, and phosphate glass.

In some embodiments, the protective layer 16 is configured to prevent the encapsulation layer 15 from being damaged by external forces.

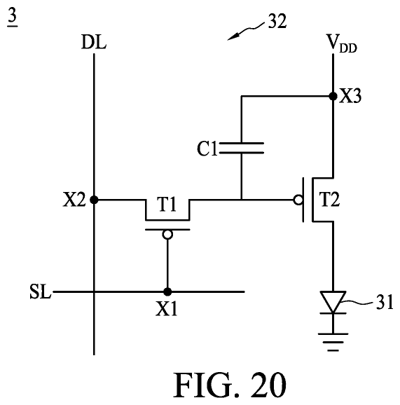

In some embodiments, the display device utilizes a plurality of pixel-driving circuits that are arranged in matrices and that can emit light of different colors to achieve the function of displaying images. With reference to FIG. 20, in some embodiments, a pixel-driving circuit 3 includes a light-emitting unit 31 and a driving portion 32. The driving portion 32 is configured to send a driving current through the light-emitting unit 31. The light-emitting unit 31 is driven by the driving current from the driving portion 32 to emit light with a luminance that corresponds to a magnitude of the driving current. In some embodiments, the light-emitting unit 31 includes an organic light-emitting diode (OLED).

Various kinds of circuits can serve as the driving circuit for driving the light-emitting unit 31, and the driving portion 32 can adopt a configuration that includes a drive circuit of a 5T/1C type, a 4T/1.0 type, a 3T/1C type, a 2T/1C type or the like. Here, a in a term of “αT/1C type” means the number of transistors, and “1C” means that a capacitance portion includes one hold capacitor.

In some embodiments, the 2T/1C type drive configuration is adopted to the pixel-driving circuit 1. The driving portion 32 includes a first transistor T1, a second transistor T2, and a capacitor C1. Each of the first and second transistors T1, T2 includes a first terminal, a second terminal, and a gate terminal.

The gate terminal of the first transistor T1 is coupled to a scan line SL at a node X1 adapted for receiving a scan signal from the scan line SL. The first terminal of the first transistor T1 is coupled to a data line DL at a node X2 for receiving a data signal from the data line DL. The second terminal of the first transistor T1, the gate terminal of the second transistor T2, and one end of the capacitor C1 are electrically connected. The other end of the capacitor C1 is coupled to a V_{DD} line V_{DD} at a node X3. The first terminal of the second transistor T2 is coupled to the V_{DD} line V_{DD} at the node X3. The second terminal of the second transistor T2 is electrically coupled to the light-emitting unit 31.

Each of the first and second transistors T1, T2 can be a P-channel transistor or an N-channel transistor. In an embodiment, the first and second transistors T1, T2 are of the same transistor type, i.e., either P-channel or N-channel. It should be noted that it is also possible to adopt a structure in which the transistors are formed on a semiconductor substrate or the like. In some embodiments, a structure of each of the transistors composing the driving portion 32 is by no means limited, and it is possible to use an insulated gate field-effect transistor (in general, a Thin Film Transistor (TFT)) typified by a MOSFET (Metal Oxide Semiconductor Field-Effect Transistor). In some embodiments, each of the transistors composing the driving portion 32 may be any of an enhance type or a depletion type, or may also be any of a single-gate type or a dual-gate type.

Although an illustration is omitted here, a circuit array portion may include a plurality of the pixel-driving circuits 3, which are two-dimensionally disposed in a matrix. That is, a plurality of vertical scan lines SL are wired so as to correspond to the rows for the pixel-driving circuits 3, and a plurality of data lines DL are wired so as to correspond to the columns for the pixel-driving circuits 3.

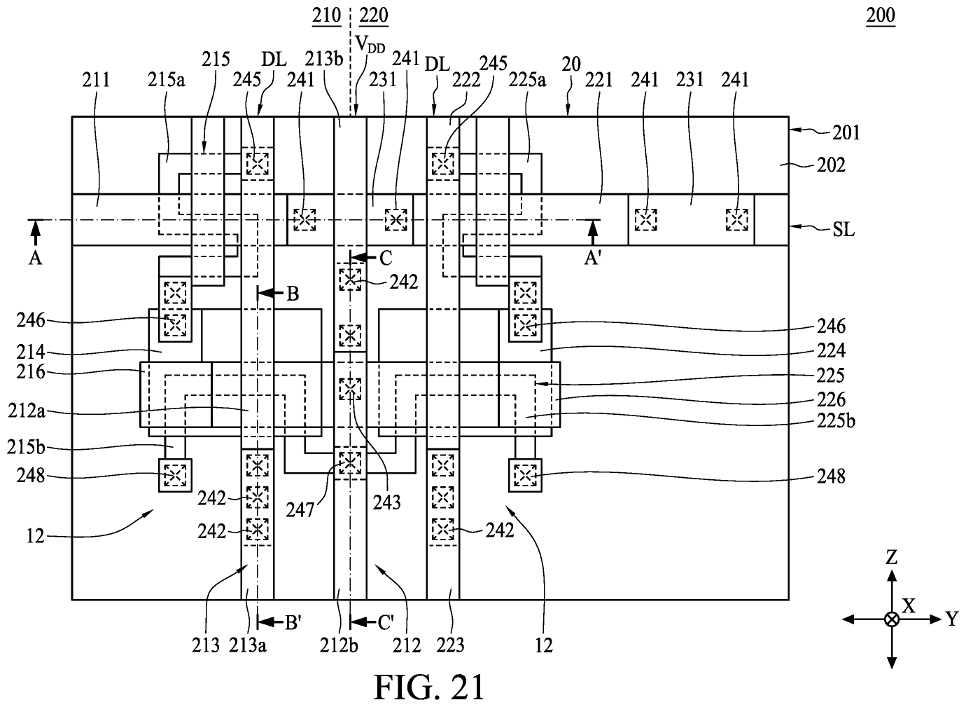

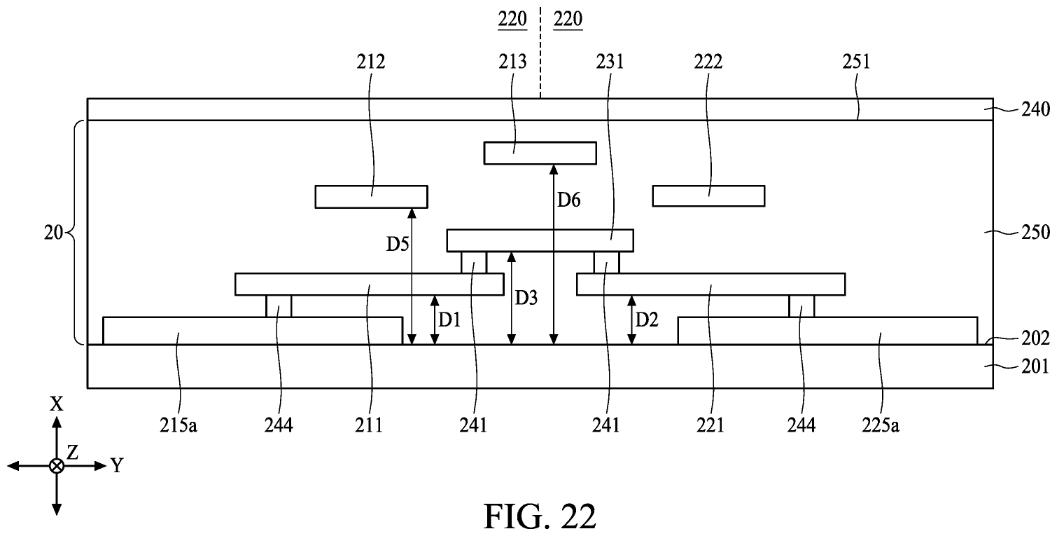

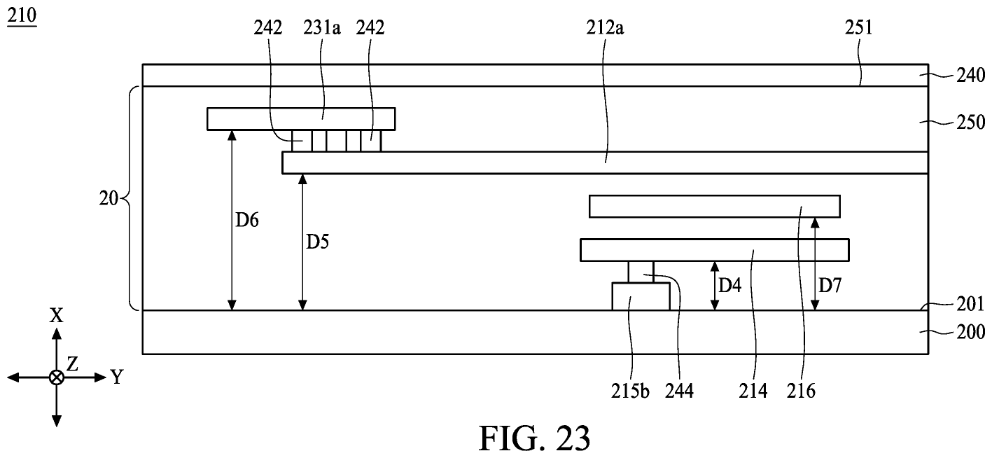

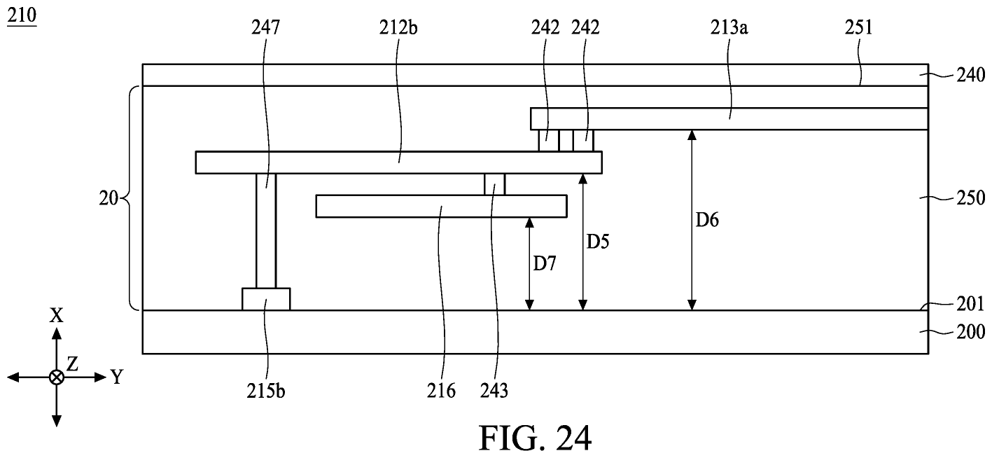

FIG. 21 is top view illustrating a display device according to aspects of the present disclosure in some embodiments. FIG. 22 is a schematic cross-sectional view taken along a line A-A′ in FIG. 21. FIG. 23 is a schematic cross-sectional view taken along a line B-B′ in FIG. 21. FIG. 24 is a schematic cross-sectional view taken along a line C-C′ in FIG. 21. In some embodiments, the display device 200 is a display device.

Referring to FIGS. 21 and 22, the display device 200 includes a circuit portion 20 over a surface 202 of a substrate 201. The circuit portion 20 includes a first portion 210 configured to drive a light-emitting pixel, a second portion 220 configured to drive another light-emitting pixel, and a bridge layer 231. The first portion 210 includes a first conductive layer 211. The first conductive layer 211 extends in a Y direction, wherein the Y direction is different from an X direction. The X direction is perpendicular to the upper surface of the substrate. The second portion 220 includes a second conductive layer 221. The second conductive layer 221 extends in the Y direction. The bridge layer 231 is configured to electrically connect the first conductive layer 211 to the second conductive layer 221. The bridge layer 231 is arranged in a manner to be offset from the first conductive layer 211 and the second conductive layer 221. In some embodiments, the Y direction is substantially perpendicular to the X direction.

Compared to an integrally formed conductive layer, the figuration of the separate first and second conductive layers 211, 221 may prevent accumulation of charge in a single conductive layer by an antenna effect, reduce the chance of loading effects during production, and significantly reduce the tensile stress when the the display device 200 is bent. The separate first conductive layer 211 and the second conductive layer 221 are spaced apart from each other and electrically connected by, the bridge layer 231, which is arranged in a manner to be offset from the first conductive layer 211 and the second conductive layer 221. The first conductive layer 211 and the second conductive layer 221 can be designed to have the same or different sizes, shapes, and line widths as desired, and can include the same or different conductive materials. In some embodiments, the conductive material can be, for example but not limited to, a metal or a metal alloy. In some embodiments, each of the first conductive layer 211, the second conductive layer 221 and the bridge layer 231 is disposed in a strip shape from a top view. In some embodiments, the length of the strip of the bridge layer 231 is less than the length of the strip of the first conductive layer 211 or the length of the strip of the second conductive layer 221. In some embodiments, the first conductive layer 211 and the second conductive layer 221 may be arranged in any directions perpendicular to the X direction. In some embodiments, the first conductive layer 211 and the second conductive layer 221 may both be arranged in the Y direction or may both be arranged in a Z direction, wherein the Z direction is different from the X direction and the Y direction, and the Y direction and the Z direction may be perpendicular to each other, or may otherwise form an included angle greater than zero. In some embodiments, the Z direction is substantially perpendicular to the X direction and the Y direction.

In some embodiments, a distance D1 between the first conductive layer 211 and the surface 202 of the substrate 201 can be the same as or different from a distance D2 between the second conductive layer 221 and the surface 202 of the substrate 201. A distance D3 between the bridge layer 231 and the surface 202 of the substrate 201 is different from the distance D1 and different from the distance D2. In some embodiments, the distance D1 and the distance D2 are the same, and the first conductive layer 211 and the second conductive layer 221 can be formed in the same step when manufacturing the display device 200. In some embodiments, the distance D3 is greater than each of the distance D1 and the distance D2 as shown in FIG. 22. In some embodiments, the distance D3 is less than each of the distance D1 and the distance D2.

In some embodiments, the bridge layer 231 is directly in contact with the first conductive layer 211 and/or the second conductive layer 221. In some embodiments, the circuit portion 20 further includes a plurality of conductive vias 241 configured to electrically connect the first conductive layer 211 to the bridge layer 231, or to electrically connect the second conductive layer 221 to the bridge layer 231. In some embodiments, the shape and size of each of the conductive vias 241 are not particularly limited, and may be adjusted according to the actual needs. The conductive vias 241 can be designed to have the same or different sizes and shapes as desired, and adjacent conductive vias 241 may include the same or different conductive materials, in some embodiments, the conductive material can be, for example but not limited to, a metal or a metal alloy. The conductive vias 241 shown in FIG. 22 are disposed at the two ends of the bridge layer 231.

In some embodiments, the circuit portion 20 of the semiconductor structure 200 is a circuit array portion. In some embodiments, the circuit portion 20 corresponds to one or more driving portion 32 of the pixel-driving circuit 3 shown in FIG. 20. In some embodiments, a plurality of portions such as the first portion 210 and the second portion 220 are arranged in matrices in the circuit portion 20, in which two exemplary portions are shown. In some embodiments, each of the first portion 210 and the second portion 220 corresponds to the driving portion 32 shown in FIG. 20.

In some embodiments, the first conductive layer 211, the second conductive layer 221 and the bridge layer 231 are electrically connected to form the scan line SL. In some embodiments, the scan line SL includes a plurality of first conductive layers 211 and a plurality of second conductive layers 221 arranged alternately, and the scan line SL further includes a plurality of bridge layers 231 electrically connected to the adjacent first conductive layer 211 and the adjacent second conductive layer 221. In some embodiments, the scan line SL, including the first conductive layer 211, the second conductive layer 221 and the bridge layer 231, also serves as the gate terminal of the first transistor T1. In some embodiments, the scan line SL extends in the Y direction.

In some embodiments, each of the first portion 210 and the second portion 220 of the circuit portion 20 further includes a third conductive layer 214, 224. The third conductive layers 214, 224 are electrically isolated. Each of the third conductive layers 214, 224 can be designed to have the same or different sizes and shapes, and can include the same or different conductive materials. In some embodiments, the conductive material can be, for example but not limited to, a metal or a metal alloy. In some embodiments, each of the third conductive layers 214, 224 is a rectangle or a square from a top view.

In some embodiments, each of the third conductive layers 214, 224 is configured to serve as the gate terminal of the second transistor T2 of the corresponding first portion 210 or second portion 220.

In some embodiments, a distance D4 between the third conductive layer 214 and the surface 202 of the substrate 201 can be the same as or different from the distance D1. The distance between the third conductive layer 224 and the surface 202 of the substrate 201 can be the same as or different from the distance D2. In some embodiments, the distance D1 and the distance D4 are the same. In some embodiments, the distance D2 and the distance between the third conductive layer 224 and the surface 202 of the substrate 201 are the same. In some embodiments, the distance D1, the distance D2, the distance D4, and the distance between the third conductive layer 224 and the surface 202 of the substrate 201 are the same, and the first conductive layer 211, the second conductive layer 221 and the third conductive layers 214, 224 can be formed in the same step when manufacturing the display device 200.

In some embodiments, the distance D3 is different from the distance D4 and different from the distance between the third conductive layer 224 and the surface 202. In some embodiments, the distance D3 is greater than each of the distance D4 and the distance between the third conductive layer 224 and the surface 202.

In some embodiments, the third conductive layers 214, 224 are disposed on the same side of the connected first conductive layer 211, the second conductive layer 221 and the bridge layer 231 from a top view.

Referring to FIGS. 21, 23 and 24, in some embodiments, the first portion 210 further includes a fourth conductive layer 212 and the second portion 220 further includes a fourth conductive layer 222. In some embodiments, each of the fourth conductive layers 212, 222 may be arranged in any direction perpendicular to the X direction. In some embodiments, the fourth conductive layers 212, 222 extend in the Z direction.

In some embodiments, the first portion 210 further includes a fifth conductive layer 213 and the second portion 220 further includes a fifth conductive layer 223. The first conductive layer 211, the bridge layer 231, the fourth conductive layer 212 and the fifth conductive layer 213 are arranged in an offset manner. In some embodiments, the fourth conductive layer 212 and the fifth conductive layer 213 are electrically connected. In some embodiments, each of the fifth conductive layers 213, 223 may be arranged in any direction perpendicular to the X direction. In some embodiments, the fifth conductive layers 213, 223 extend in the Z direction. In some embodiments, the fourth conductive layers 212, 222 and the fifth conductive layers 213, 223 extend in the same direction.

The fourth conductive layers 212, 222 and the fifth conductive layers 213, 223 can be designed to have the same or different sizes, shapes, and line widths as desired, and can include the same or different conductive materials. In some embodiments, the conductive material can be, for example but not limited to, a metal or a metal alloy. In some embodiments, each of the fourth conductive layers 212, 222 and the fifth conductive layers 213, 223 is disposed in a strip shape from a top view.

In some embodiments, a distance D5 between the fourth conductive layer 212 and the surface 202 of the substrate 201 is greater than the distance D1, In some embodiments, the distance D5 is greater than the distance D3. In some embodiments, a distance D6 between the fifth conductive layer 213 and the surface 202 of the substrate 201 is different from the distance D5. That is, the distance D6 may be greater than or less than the distance D5. In some embodiments, the distance D1, the distance D3, the distance D5 and distance D6 are different. In some embodiments, the distance D6 is greater than the distance D5.

In some embodiments, the fourth conductive layer 212 includes a conductive film 212a and a conductive film 212b. In some embodiments, the conductive film 212a is configured to serve as a portion of the data line DL and the conductive film 212b is configured to serve as a portion of the V_{DD} line V_{DD} for the first portion 210.

In some embodiments, the fifth conductive layer 213 includes a conductive film 213a and conductive film 213b. In some embodiments, the conductive film 212a and the conductive film 213a are electrically connected and configured to serve as the data line DL for the first portion 210. In some embodiments, the fourth conductive layer 222 and the fifth conductive layer 223 are electrically connected and configured to serve as the data line DL for the second portion 220. In some embodiments, the conductive film 212b and the conductive film 213b are electrically connected and configured to serve as the V_{DD} line V_{DD} for the first portion 210 and the second portion 220.

In some embodiments, the conductive films 213a, 213b of the fifth conductive layer 213 are directly in contact with the conductive films 212a, 212b of the fourth conductive layer 212, respectively. In some embodiments, the circuit portion 20 further includes a plurality of conductive vias 242 configured to electrically connect the conductive film 212a to the conductive film 213a, and/or electrically connect the conductive film 212b to the conductive film 213b. In some embodiments, the design and materials of the conductive via 242 may be similar to or different from the design and materials of the conductive via 241, and the details are omitted herein for brevity.

In some embodiments, the data line DL and the V_{DD} line V_{DD} of the first portion 210 extend in a direction perpendicular to the X direction. In some embodiments, the data line DL and the V_{DD} line V_{DD} extend in a direction different from the Y direction. In some embodiments, the data line DL is parallel to the V_{DD} line V_{DD} from a top view. In some embodiments, the data line DL and the V_{DD} line V_{DD} of the first portion 210 both extend in the Z direction.

In some embodiments, the V_{DD} line V_{DD} is shared by the first portion 210 and the second portion 220. In some embodiments, the V_{DD} line V_{DD} represents the boundary between the first portion 210 and the second portion 220.

In some embodiments, the fourth conductive layer 212 and the fifth conductive layer 213 are alternately arranged from a top view. In some embodiments, the conductive film 212a of the fourth conductive layer 212 is adjacent to the conductive film 213b of the fifth conductive layer 213 from a top view. In some embodiments, the conductive film 212b of the fourth conductive layer 212 is adjacent to the conductive film 213a of the fifth conductive layer 213 from a top view.

In some embodiments, each of the first portion 210 and the second portion 220 of the circuit portion 20 further includes a sixth conductive layer 216, 226. In some embodiments, the sixth conductive layers 216, 226 are integrally formed. In some embodiments, each of the sixth conductive layers 216, 226 is configured to serve as the capacitor C1 of the corresponding the first and second portions 210, 220.

In some embodiments, a distance D7 between the sixth conductive layer 216 and the surface 202 of the substrate 201 can be the same as or different from the distance D3. In some embodiments, the distance D7 is greater than the distance D4 and less than the distance D6, In some embodiments, the distance D7 is greater than the distance D4 and less than the distance D5. In some embodiments, the distance D7 and the distance D3 are the same, and the bridge layer 231 and the sixth conductive layers 216, 226 can be formed in the same step when manufacturing the display device 200.

In some embodiments, the sixth conductive layers 216, 226 are disposed above the third conductive layers 214, 224, respectively, from a top view. In some embodiments, the sixth conductive layers 216, 226 are disposed below the fourth conductive layers 212, 222, respectively, from a top view.

In some embodiments, the circuit portion 20 further includes a conductive via 243 configured to electrically connect the sixth conductive layers 216, 226 to the conductive film 212b of the fourth conductive layer 212 or the conductive film 213b of the fifth conductive layer 213. In some embodiments, the conductive via 243 is configured to electrically connect the V_{DD} line V_{DD} to the integrally formed sixth conductive layers 216, 226. In some embodiments, the conductive via 243 may correspond to the node X3 of the pixel-driving circuit 3 shown in FIG. 20. In some embodiments, the design and materials of the conductive via 243 may be similar to or different from the design and materials of the conductive via 241, and the details are omitted herein for brevity.

In some embodiments, the first portion 210 further includes a conductive channel layer 215 disposed on the surface 202 of the substrate 201, and the second portion 220 further includes a conductive channel layer 225 disposed on the surface 202 of the substrate 201. In some embodiments, the conductive channel layers 215, 225 include polysilicon. In some embodiments, the distance between the conductive channel layers 215, 225 and the surface 202 of the substrate 201 is less than the distance D1. In some embodiments, the conductive channel layers 215, 225 are directly disposed on the surface 202 of the substrate 201.

In some embodiments, the conductive channel layer 215 of the first portion 210 includes a first conductive channel film 215a and a second conductive channel film 215b. In some embodiments, the first conductive channel film 215a is electrically connected to the first conductive layer 211. In some embodiments, the second conductive channel film 215b is electrically connected to the third conductive layer 214. In some embodiments, the conductive channel layer 225 of the second portion 220 includes a first conductive channel film 225a and a second conductive channel film 225b. In some embodiments, the first conductive channel film 225a is electrically connected to the second conductive layer 221. In some embodiments, the second conductive channel film 225b is electrically connected to the third conductive layer 224.

In some embodiments, the first conductive channel film 215a of the first portion 210 is in contact with the first conductive layer 211. In some embodiments, the second conductive channel film 215b of the first portion 210 is in contact with the third conductive layer 214. In some embodiments, the first conductive channel film 225a of the second portion 220 is in contact with the second conductive layer 221. In some embodiments, the second conductive channel film 225b of the second portion 220 is in contact with the third conductive layer 224. In some embodiments, the circuit portion 20 further comprises a plurality of conductive vias 244 configured to electrically connect the first conductive layer 211 to the first conductive channel film 215a, configured to electrically connect the third conductive layer 214 to the second conductive channel film 215b, configured to electrically connect the second conductive layer 221 to the first conductive channel film 225a, or configured to electrically connect the third conductive layer 224 to the second conductive channel film 225b. In some embodiments, the design and materials of the conductive via 244 may be similar to or different from the design and materials of the conductive via 241, and the details are omitted herein for brevity.

In some embodiments, each of the first conductive channel films 215a, 225a is configured to serve as the first terminal and second terminal of the first transistor T1 of the pixel-driving circuit 3 shown in FIG. 20. In some embodiments, each of the second conductive channel films 215b, 225b is configured to serve as the first terminal and second terminal of the second transistor T2 of the pixel-driving circuit 3 shown in FIG. 20.

In some embodiments, the shape of each of the first and second conductive channel films 215a, 215b, 225a, 225b may be, but is not limited to, a long stripe. In some embodiments, the shape of each of the first and second conductive channel films 215a, 215b, 225a, 225b is a long strip bent into an S shape from a top view. In some embodiments, the shape of each of the first and second conductive channel films 215a, 215b, 225a, 225b is a long strip with many bends from a top view.

In some embodiments, one end of the first conductive channel film 215a is electrically connected to the conductive film 212a of the fourth conductive layer 212 or the conductive film 213a of the fifth conductive layer 213. In some embodiments, one end of the first conductive channel film 215a is electrically connected to the data line DL. In some embodiments, the electrical connection of the first conductive channel film 215a and the data line DL may correspond to the node X2 of the pixel-driving circuit 3 shown in FIG. 20. In some embodiments, a conductive via 245 is configured to electrically connect the one end of the first conductive channel film 215a to the conductive film 212a of the fourth conductive layer 212. In some embodiments, the conductive via 245 is configured to electrically connect one end of the first conductive channel film 225a to the conductive film 222a of the fourth conductive layer 222. In some embodiments, the design and materials of the conductive via 245 may be similar to or different from the design and materials of the conductive via 241, and the details are omitted herein for brevity.

In some embodiments, the other end of the first conductive channel film 215a is electrically connected to the third conductive layer 214 and the sixth conductive layer 216. In some embodiments, a conductive via 246 is configured to electrically connect the other end of the first conductive channel film 215a to the fifth conductive layer 214 and sixth conductive layers 216. In some embodiments, the conductive via 246 is configured to electrically connect the other end of the first conductive channel film 225a to the fifth conductive layer 224 and the sixth conductive layers 226. In some embodiments, the design and materials of the conductive via 246 may be similar to or different from the design and materials of the conductive via 241, and the details are omitted herein for brevity.

In some embodiments, one end of the second conductive channel film 215b is electrically connected to the conductive film 212b of the fourth conductive layer 212 or the conductive film 213b of the fifth conductive layer 213. In some embodiments, one end of the second conductive channel film 215b is electrically connected to the V_{DD} line V_{DD}. In some embodiments, the electrical connection of the second conductive channel film 215b and the V_{DD} line V_{DD} may correspond to the node X3 of the pixel-driving circuit 3 shown in FIG. 20. In some embodiments, a conductive via 247 is configured to electrically connect the one end of the second conductive channel film 215b to the conductive film 212b of the fourth conductive layer 212. In some embodiments, the conductive via 247 is configured to electrically connect the one end of the second conductive channel film 225b to the conductive film 212b of the fourth conductive layer 212. In some embodiments, the other end of the second conductive channel film 215b is electrically connected to an electroluminescent layer 240. In some embodiments, a conductive via 248 is configured to electrically connect the other end of the second conductive channel film 215b to an electroluminescent layer 240. In some embodiments, the conductive via 248 is configured to electrically connect the other end of the second conductive channel film 225b to the electroluminescent layer 240.

In some embodiments, the substrate 201 is flexible and can be normally operated while being bent by an external force. In some embodiments, the substrate 11 has different bending capabilities depending on composition and structure, and can be made of different materials according to different needs. Materials of the substrate 201 may be similar to or different from the materials of the substrate 11 as described above, and the details of the materials of the substrate 201 are omitted herein for brevity.

In some embodiments, the display device 200 includes a dielectric layer 250. The dielectric layer 250 is disposed over a surface 202 of a substrate 200 in the circuit portion 20, and the conductive layers and the conductive vias are disposed within the dielectric layer 250. Materials of the dielectric layer 250 may be similar to or different from the materials of the dielectric layer 121 as described above, and the details of the materials of the dielectric layer 250 are omitted herein for brevity.

In some embodiments, the light-emitting layer 240 is disposed over a surface 251 of the dielectric layer 250 in the circuit portion 20. In some embodiments, the light-emitting layer 240 may correspond to the light-emitting unit 31 of the pixel-driving circuit 3 shown in FIG. 20. Design and materials of the light-emitting layer 240 may be similar to or different from the design and materials of the pixel layer 13 described above, and the details of the materials of the light-emitting layer 240 are omitted herein for brevity.

Accordingly, the present disclosure provides a display device. The display device includes a substrate and a circuit layer stacked on the substrate. The circuit layer includes a wire. The wire extends in a Y direction, wherein the Y direction is different from an X direction perpendicular to the upper surface of the substrate. The wire includes a plurality of conductive interconnects, wherein the adjacent conductive interconnects are electrically connected and are disposed at different distances from the upper surface of the substrate. Consequently, the configuration of the wire 122 may significantly reduce the tensile stress generated inside the wire 122 when the display device is subjected to bending, prevent accumulation of charge in a single conductive interconnect 122a by an antenna effect, and reduce the chance of loading effects during production.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed:

1. A display device, comprising:
a substrate, including an upper surface, and
a circuit layer stacked on the upper surface 110 of the substrate,
wherein the circuit layer includes a dielectric layer and a wire, and the wire extends in a Y direction, wherein the Y direction is different from an X direction, the X direction is perpendicular to the upper surface of the substrate;
wherein the wire includes a plurality of conductive interconnects disposed in the dielectric layer, the adjacent conductive interconnects are electrically connected, and adjacent conductive interconnects are disposed at different distances from the upper surface of the substrate.

2. The display device of claim 1, wherein each of the conductive interconnects has a length of between 100 um and 500 um.

3. The display device of claim 1, wherein the circuit layer further includes a conductive via configured to electrically connect adjacent conductive interconnects.

4. The display device of claim 1, further comprising a light-emitting layer disposed on the circuit layer.

5. The display device of claim 1, wherein the wire includes a plurality of conductive layers arranged in an offset manner, and each of the conductive layers includes at least one conductive interconnect.

6. A display device, comprising:
a circuit portion disposed over a surface of a substrate, the circuit portion comprising:
a first portion configured to drive a light-emitting unit, wherein the first portion includes a first conductive layer, and the first conductive layer extends in a Y direction, wherein the Y direction is different from an X direction, the X direction is perpendicular to the upper surface of the substrate;
a second portion configured to drive another light-emitting unit, wherein the second portion includes a second conductive layer, wherein the second conductive layer extends in the Y direction; and
a bridge layer extending in the Y direction, wherein the bridge layer is configured to electrically connect the first conductive layer to the second conductive layer and the bridge layer is arranged in a manner offset from the first conductive layer and the second conductive layer.

7. The display device of claim 6, wherein the Y direction is substantially perpendicular to the X direction.

8. The display device of claim 6, wherein the circuit portion further comprises a plurality of conductive vias configured to electrically connect the first conductive layer to the bridge layer, or the second conductive layer to the bridge layer.

9. The display device of claim 6, wherein a distance between the first conductive layer and the surface of the substrate is the same as a distance between the second conductive layer and the surface of the substrate.

10. The display device of claim 6, wherein the first conductive layer, the second conductive layer and the bridge layer are electrically connected to form a scan line.

11. The display device of claim 6, wherein each of the first portion of the circuit portion and the second portion of the circuit portion further includes a third conductive layer, and each of the third conductive layers serves as a gate terminal.

12. The display device of claim 11, wherein a distance between the third conductive layer and the surface of the substrate is the same as the distance between the first conductive layer and the surface of the substrate.

13. The display device of claim 6, wherein the each of the first portion and the second portion further includes:
a fourth conductive layer extending in a Z direction, wherein the Z direction is different from the X direction and the Y direction; and
a fifth conductive layer extending in the Z direction;
wherein the first conductive layer, the bridge layer, the third conductive layer and the fourth conductive layer are arranged in an offset manner, and the third conductive layer and the fourth conductive layer are electrically connected.

14. The display device of claim 13, wherein the Z direction is substantially perpendicular to the X direction.

15. The display device of claim 13, wherein the fourth conductive layer and the fifth conductive layer are electrically connected to form a data line, and the data line is electrically connected to a first transistor.

16. The display device of claim 13, wherein the fourth conductive layer and the fifth conductive layer are electrically connected to form a V_{DD} line, and the first portion and the second portion both include the V_{DD} line.

17. The display device of claim 16, wherein the V_{DD} line is electrically connected to a capacitor and a second transistor,

18. The display device of claims 11 and 13, wherein each of the first portion and the second portion further includes a sixth conductive layer serving as a capacitor, wherein the third conductive layer, the fourth conductive layer, and the fifth conductive layer are arranged in an offset manner.

19. The display device of claim 6, wherein the each of the first portion and the second portion further includes a conductive channel layer disposed on the substrate, wherein the minimum distance between the conductive channel and the substrate is less than the minimum distance between the first conductive layer and the substrate.

20. The display device of claims 15, 17 and 19, wherein the conductive channel layer includes a plurality of conductive channel films serving as source electrodes and drain electrodes of the first transistor and the second transistor.

21. The display device of claim 19, further comprising a light-emitting layer disposed over the circuit portion, wherein the light-emitting layer is electrically connected to the conductive channel layer.
